(19) United States
(12) Patent Application Publication
(10) Pub. No.: US 2005/0007160 A1
(43) Pub. Date: Jan. 13, 2005

(54) Tunable differential transconductor and adjustment method

(76) Inventor: Robert M. R. Neff, Palo Alto, CA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/616,794

(22) Filed: Jul. 10, 2003

(51) Int. Cl. H02M 11/00; H03D 1/00; H01L 21/8238

(52) U.S. Cl. 327/103

(57) ABSTRACT

The tunable differential transconductor includes a tail current sink and a differentially-connected pair of FETs connected to the tail current source. At least one of the FETs is a composite FET that includes a main FET connected in parallel with a switchable tuning element. The switchable tuning element is operable to change an effective channel dimension, i.e., at least one of effective channel length and effective channel width, of the composite FET. In the method, a differential transconductor that includes a tail current sink and a differentially-connected pair of composite FETs connected to the tail current sink is provided. The effective channel dimension of at least one of the composite FETs is changed to establish one or more of a desired transconductance, a desired transconductance linearity and a desired offset of the differential transconductor.

### TECHNICAL FIELD

The technical field of this disclosure is semiconductor circuits, particularly, tunable differential transconductors and methods of tuning the same.

### BACKGROUND OF THE INVENTION

Transconductors are used in circuits to convert voltage signals to current signals. They can be used with capacitors to form integrators or can be used in filter circuits, such as gₘ−C filters. Conventional transconductors have several advantages, including tunable transconductance, low input capacitance, and good linearity for large bias voltages, but have certain limitations.

FIG. 1 is a circuit drawing showing a conventional transconductor constructed using differential pair of MOSFETs. Differential transconductor 100 is composed of a MOSFET 102 and a MOSFET 104 connected as a differential pair. Differential input voltages Vᵢₙ₊ and Vᵢₙ₋ are received at an input terminal 106 and an input terminal 108, respectively. Input terminal 106 is connected to the gate of MOSFET 102 and input terminal 108 is connected to the gate of MOSFET 104. The drains of MOSFETs 102 and 104 are connected to current sources 114 and 115, respectively. The sources of MOSFETs 102 and 104 are connected to one another and to a tail current sink 118. Differential transconductor 100 produces differential output currents Iₒᵤₜ₋ and Iₒᵤₜ₊ at current output 110 and current output 112, respectively. Current output 110 is located at the node between the drain of MOSFET 102 and current source 114. Current output 112 is located at the node between the drain of MOS FET 104 and current source 115.

Differential transconductor 100 has a transconductance gₘ defined as the ratio of output current to input voltage (Iₒᵤₜ/Vᵢₙ). In some applications, the transconductance of transconductor 100 has to be tuned after manufacture to provide a predetermined transconductance notwithstanding production variations. The transconductor may additionally need to be tuned during operation to maintain its transconductance notwithstanding changes in environmental factors, such as operating temperature.

In differential transconductors incorporating MOSFETs operating in a saturated bias condition, the drain current I_{d} and the gate-source voltage V_{gs} have the following square-law relationship:

$${I}_{d} = \frac{k}{2} \cdot \frac{W}{L} \cdot {( {V}_{gs} - {V}_{T} )}^{2} \qquad ( 1 )$$

where k is a technology-dependent constant, W is channel width, L is channel length and (V_{gs}−V_{T}) is the difference between the gate-source voltage and the threshold voltage as will be referred to as the turn-on voltage. The transconductance gₘ is the derivative of the drain current with respect to the gate-to-source voltage V_{gs}:

$${g}_{m} = \frac{ⅆ {I}_{d}}{ⅆ {V}_{gs}} = k \cdot \frac{W}{L} \cdot ( {V}_{gs} - {V}_{T} ) \qquad ( 2 )$$

Thus, the transconductance is proportional to the turn-on voltage (V_{gs}−V_{T}), which in turn depends on the drain current I_{d}. The transconductance can be tuned by adjusting the tail current sunk by current sink 118. This method of tuning transconductance will be referred to herein as tail current tuning.

A transconductor ideally has a linear relationship between output current and input voltage. Practical transconductors have a linearity error proportional to the ratio Vₚ/(V_{gs}−V_{T}), where Vₚ is the amplitude of the input voltage. Consequently, linearity improves as the turn-on voltage (V_{gs}−V_{T}) increases.

A differential transconductor is typically designed by first selecting the W/L of the MOSFETs. For a given transconductance gₘ, a large value of the turn-on voltage (V_{gs}−V_{T}) is desirable to obtain good linearity. This in turn requires that the value of W/L be small. In high-speed circuits, a small value of L is desirable because a large input capacitance can impair the performance of the transconductor at high speeds. The input capacitance is proportional to the product W×L of the MOSFETs. For a given value of W/L, halving the value of L reduces the input capacitance by a factor or four. Therefore, using MOSFETs having a minimum practical channel length would appear desirable. However, the square law model described above only holds when the MOSFETs have a channel length larger than a process-determined minimum length. As the channel length of the MOSFETs is reduced towards the minimum length, velocity saturation causes the drain current to approach a linear function of the turn-on voltage (V_{gs}−V_{T}), i.e.:
I_{d}=k₂vₛₐₜW(V_{gs}−Vₜ) (3)
gₘ=k₂vₛₐₜW (4)
where k₂ is a second technology-dependent constant, W is the channel width and vₛₐₜ is the saturation velocity. In particular, as the channel length of the MOSFETs is reduced, the transconductance gₘ becomes less dependent on the turn-on voltage (V_{gs}−V_{T}) and, hence, on the tail current. Therefore, in differential tranconductors fabricated using MOSFETs having a channel length approaching the process-defined minimum, tail current tuning becomes a progressively less effective way of tuning the transconductance gₘ.

The current trend towards lower power supply voltages also reduces the effectiveness of tail current tuning to tune transconductance because a low power supply voltage limits the turn-on voltage (V_{gs}−V_{T}). Moreover, a lower power supply voltage also reduces the linearity that can be obtained.

Thus, what is needed is a tunable differential transconductor and method of tuning the same that would overcome the above disadvantages.

### SUMMARY OF THE INVENTION

The invention provides a tunable differential transconductor that includes a differential pair of FETs connected to a tail current sink. At least one of the FETs is a composite FET having an effective channel dimension that can be changed to tune the differential transconductor. Tunable parameters include offset, transconductance and transconductance linearity. In one embodiment, the tail current is fixed and the transconductance tuning is performed by changing the effective channel dimension. In another embodiment, the transconductance is tuned by tail current tuning and the effective channel dimension is changed to provide a desired transconductance linearity at that conductance. Changing the effective channel dimension to compensate for process and environmental variations avoids the need to trade high current for linearity.

The invention allows the range of tail current variation to be reduced, MOSFETs with shorter channel lengths to be used, or some of both. Reducing the range of tail current variation increases the transconductance linearity with reduced power supply voltage. A shorter channel length allows the maximum channel width to be reduced, resulting in a lower total input capacitance.

One aspect of the invention provides a tunable differential transconductor that includes a tail current source and a differentially-connected pair of FETs connected to the tail current source. At least one of the FETs is a composite FET composed of a main FET connected in parallel with a switchable tuning element. The switchable tuning element is operable to change the effective channel dimension of the composite FET. The effective channel dimension is at least one of the effective channel width and the effective channel length of the composite FET. The switchable tuning element is composed of an auxiliary FET and a switch connected in series between the source the drain of the main FET. In an embodiment, the switchable tuning element is composed of series circuits connected in parallel between the source and the drain of the main FET. Each series circuit is composed of an auxiliary FET connected in series with a switch.

Another aspect of the present invention provides a method for tuning a differential transconductor. In the method, a differential transconductor composed of a tail current sink and a differentially-connected pair of composite FETs connected to the tail current sink is provided. The composite FETs have a respective effective channel dimension. The effective channel dimension of at least one of the composite FETs is changed to establish one or more of a desired offset, a desired transconductance and a desired transconductance linearity of the differential transconductor.

The foregoing and other features and advantages of the invention will become further apparent from the following detailed description of presently preferred embodiments, read in conjunction with the accompanying drawings. The detailed description and drawings are merely illustrative of the invention, rather than limiting the scope of the invention defined by the appended claims and equivalents thereof.

### BRIEF DESCRIPTION OF THE DRAWINGS

FIG. 1 is a circuit diagram showing a conventional transconductor constructed using a differential pair of MOSFETs;

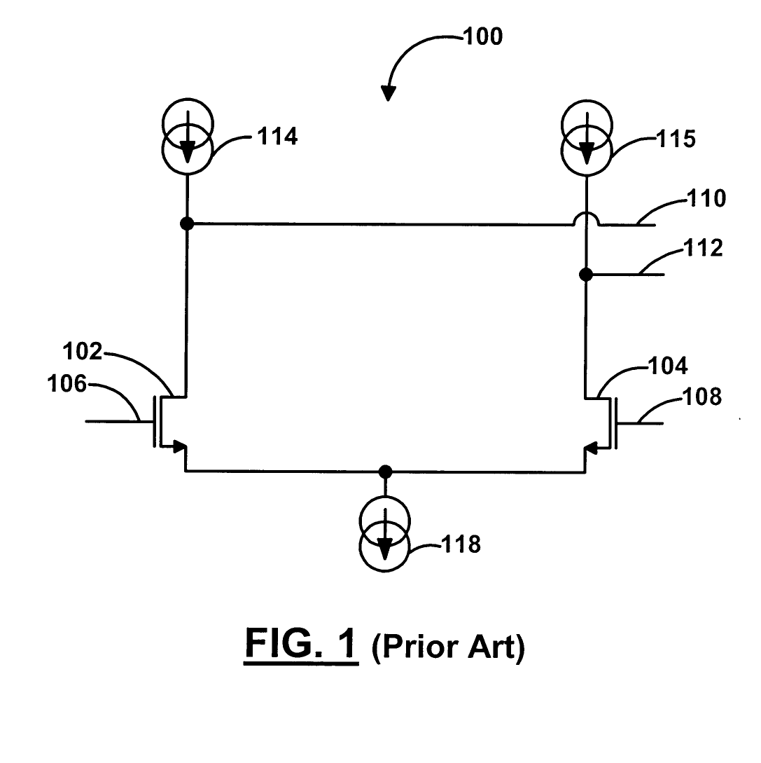

FIG. 2 is a circuit diagram showing a first embodiment of a tunable differential transconductor in accordance with the invention;

FIG. 3 is a circuit diagram showing a second embodiment of a tunable differential transconductor in accordance with the invention;

FIG. 4 is a flow chart illustrating a first embodiment of a method in accordance with the invention for tuning a tunable differential transconductor; and

FIG. 5 is a flow chart illustrating a second embodiment of a method in accordance with the invention for tuning a tunable differential transconductor.

### DETAILED DESCRIPTION OF PRESENTLY PREFERRED EMBODIMENTS

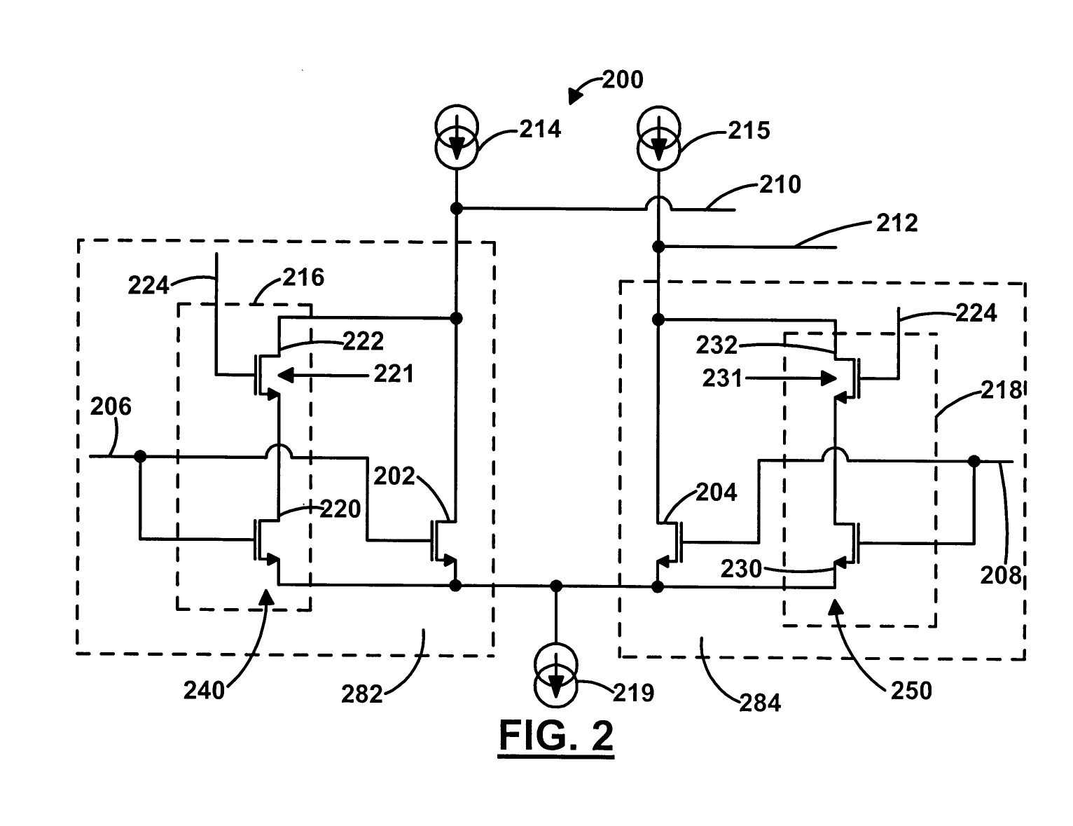

FIG. 2 is a circuit diagram showing a first embodiment 200 of a tunable differential transconductor in accordance with the invention. Differential transconductor 200 is composed of a composite FET 282 and a composite FET 284 connected as a differential pair. Each composite FET is composed of a main FET and a switchable tuning element connected in parallel. The switchable tuning element is operable to change an effective channel dimension of the composite FET.

Composite FET 282 is composed of a main FET 202 and a switchable tuning element 216 connected in parallel. Switchable tuning element 216 is a series circuit 240 composed of an auxiliary FET 220 and a switch 221 connected in series. Series circuit 240 is connected between the source and the drain of main FET 202 and the gate of auxiliary FET 220 is connected to the gate of main FET 202 to connect switchable tuning element 216 in parallel with main FET 202. The nodes where switchable tuning element 216 connects to the drain, gate and source of main FET 202 constitute the drain, gate and source, respectively, of composite FET 282.

In the example of switchable tuning element 216 shown in FIG. 2, a switching FET 222 constitutes switch 221. Auxiliary FET 220 is connected in series with switching FET 222 by connecting the source of switching FET 222 to the drain of auxiliary FET 220. Tuning control signal 224 is connected to the gate of switching FET 222 of switchable tuning element 216. Switching FET 222 operates in response to control signal 224 to connect auxiliary FET 220 in parallel with main FET 202 and change the effective channel dimension of composite FET 282. The effective channel dimension is at least one of effective channel width and effective length.

Composite FET 284 is composed of a main FET 204 and a switchable tuning element 218 connected in parallel. Switchable tuning element 218 is a series circuit 250 composed of an auxiliary FET 230 and a switch 231 connected in series. Series circuit 250 is connected between the source and the drain of main FET 204 and the gate of auxiliary FET 230 is connected to the gate of main FET 204 to connect switchable tuning element 218 in parallel with main FET 204. The nodes where switchable tuning element 218 connects to the drain, gate and source of main FET 204 constitute the drain, gate and source, respectively, of composite FET 284.

In the example of switchable tuning element 218 shown in FIG. 2, a switching FET 232 constitutes switch 231. Auxiliary FET 230 is connected in series with switching FET 232 by connecting the source of switching FET 232 to the drain of auxiliary FET 230. Alternatively, auxiliary FET 230 may be connected in series with switching FET 232 by connecting the source of auxiliary FET 230 to the drain of switching FET 232. Tuning control signal 224 is connected to the gate of switching FET 232 of switchable tuning element 218. Switching FET 232 operates in response to control signal 224 to connect auxiliary FET 220 in parallel with main FET 204 to change the effective channel dimension of composite FET 284. The effective channel dimension is at least one of effective channel width and effective length.

Differential input voltages Vᵢₙ₊ and Vᵢₙ₋ are received via input terminal 206 and input terminal 208, respectively. Input terminal 206 is connected to the gate of composite FET 282 and input terminal 208 is connected to the gate of composite FET 284. The drains of composite FETs 282 and 284 are connected to current sources 214 and 215, respectively. The sources of composite FETs 282 and 284 are connected to one another and to a tail current sink 219. Tunable differential transconductor 200 produces differential output currents Iₒᵤₜ₋ and Iₒᵤₜ₊ at current output 210 and current output 212, respectively. Current output 210 is located at the node between the drain of composite FET 282 and current source 214. Current output 212 is located at the node between the drain of composite FET 284 and current source 215.

Main FETs 202, 204 can be MOSFETs or J-FETs. Auxiliary FETs 220, 230 can be MOSFETs or J-FETs.

Switches 221, 231 can be MOSFETs 222, 232 as shown, J-FETs or some other type of switching elements. Switches 221, 231 having a low ON resistance provides composite FETs 282, 284 with properties that more closely match those of an individual FET. With a low ON resistance, the voltage drops across the switches are small relative to the turn-on voltage of the main FETs and the auxiliary FETs. In some embodiments, switching elements used as switches 221, 231 operate in response to tuning control signal 224, as described above. In other embodiments, switching elements as simple as mechanical switches, bridgeable or fusible links, for example, are used as switches 221, 231. Such switching elements do not operate in response to a tuning control signal. Switches 221, 231 may be connected in series with the sources of auxiliary FETs 220, 230, respectively, instead of in series with the drains of these FETs as in the example shown.

MOSFETs 222, 232 used as switches 221, 231 may be n-channel MOSFETs or p-channel MOSFETs, depending on the signal levels of tuning control signal 224.

Tuning control signal 224 may be generated using NMOS or PMOS FETs. Typically, a full-swing CMOS logic signal is used as the tuning control signal.

In the example shown in FIG. 2, both of FETs 282 and 284 are composite FETs. However, this is not critical. Only one of FETs 282 and 284 need be a composite FET: the other may be an FET similar to the main FET of the composite FET. The effective channel dimension of a single composite FET may be changed as described above to tune the output offset of the transconductor 200.

In the example of tunable differential transconductor 200 shown, tuning control signal 224 causes switching FETs 222, 232 to connect auxiliary FETs 220, 230, respectively, in parallel with main FETs 202 and 204, respectively, to change the effective channel width of composite FETs 282, 284. Changing the effective channel width of the composite FETs changes their transconductance gₘ regardless of whether the transconductance is primarily determined by the width-to-length ratio (normal case) or the width only (velocity saturation/low supply voltage case). Changing the effective channel width of the composite FETs may be used to tune either or both of the transconductance and the transconductance linearity of transconductor 200.

FIG. 2 shows an example in which control signal 224 is a single-bit digital control signal. When tuning control signal 224 is in its OFF state, switching FET 222 is OFF. This effectively disconnects auxiliary FET 220 from the circuit, and the effective channel width of composite FET 282 is W, i.e., the channel width of main FET 202. When control signal 224 is in its ON state, switching FET 222 is ON and connects auxiliary FET 220 in parallel with main FET 202. Current from first current output 210 and current source 214 flows through both main FET 202 and auxiliary FET 220. Thus, when control signal 224 is in its ON state, the effective channel width of composite FET 282 is W+ΔW, i.e., the channel width W of main FET 202 plus the channel width ΔW of auxiliary FET 220 of switchable tuning element 216.

Similarly, when tuning control signal 224 is in its OFF state, switching FET 232 is OFF. This effectively disconnects auxiliary FET 230 from the circuit, and composite FET 284 has an effective channel width of W, the channel width of main FET 204. When tuning control signal 224 is in its ON state, switching FET 232 is in its ON state and connects auxiliary FET 230 in parallel with main FET 204 to change the effective channel width of composite FET 284 to W+ΔW, i.e., the channel width W of main FET 204 plus the channel width ΔW of auxiliary FET 230.

In the above example, tuning control signal 224 is provided to both composite FETs 282 and 284. However, different tuning control signals may be provided to the composite FETs. Using different tuning control signals additionally or alternatively allows the transconductor offset to be tuned.

In the example described above, auxiliary FETs 220, 230 have the same channel lengths as main FETs 202 and 203. As a result, composite FETs 282, 284 having unchangeable channel lengths and changeable effective channel widths. The changes in the effective channel width change the transconductance of the composite FETs, as noted above. In another embodiment, the channel lengths of auxiliary FETs 220, 230 and main FETs 202, 204 differ. Auxiliary FETs with channel lengths that differ from the channel lengths of the respective main FETs change the effective dimension of the composite FETs by changing the effective channel length, and, hence, the effective width-to-length ratio (W/L) of composite FETs 282, 284. The general rule for combining individual FETs to get the composite effective dimension is to add the W/L ratios:
(W/L)_{Effective}=(W/L)₁+(W/L)₂+ . . . +(W/L)_{N}. (5)

Auxiliary FETs with minimum-width channels and channel lengths that differ from the channel lengths of the respective main FETs are useful for effecting small changes in the transconductance of transconductor 200.

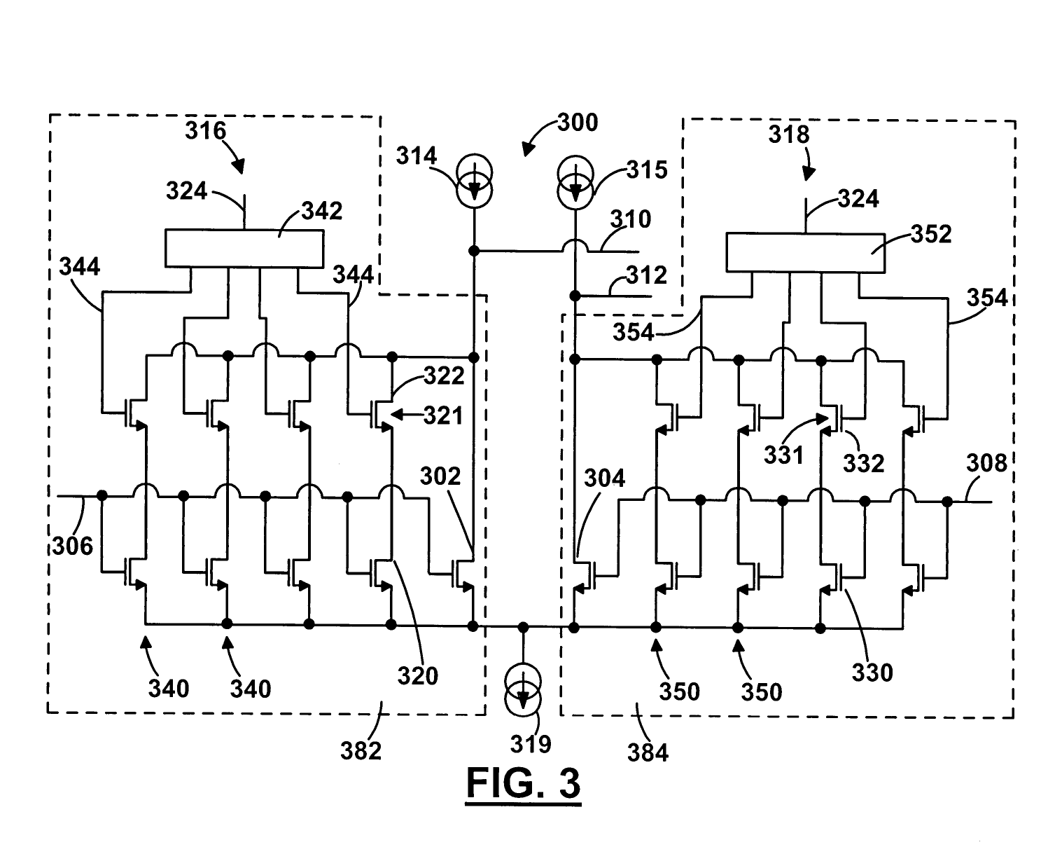

FIG. 3 is a circuit diagram showing a second embodiment of a tunable differential transconductor in accordance with the invention. Differential transconductor 300 is composed of a composite FET 382 and a composite FET 384 connected as a differential pair. Each composite FET is composed of a main FET and a switchable tuning element connected in parallel. In this embodiment, the switchable tuning element is composed of series circuits each composed of an auxiliary FET and a switch connected in series. The series circuits are connected in parallel between the source and the drain of the main FET. The gates of the auxiliary FETs are connected to the gate of the main FET. The switchable tuning element is operable to change an effective channel dimension of the composite FET. The series circuits constituting the switchable tuning element can be individually or multiply activated to provide a more precise tuning of the effective channel dimension of the composite FET.

Composite FET 382 is composed of a main FET 302 and a switchable tuning element 316 connected in parallel. Switchable tuning element 316 is composed of series circuits 340. Each series circuit 340 is composed of an auxiliary FET 320 and a switch 321 connected in series. Series circuits 340 are connected in parallel between the source and the drain of main FET 302 and the gates of auxiliary FETs 320 are connected to the gate of main FET 302. The nodes where switchable tuning element 316 connects to the drain, gate and source of main FET 302 constitute the drain, gate and source, respectively, of composite FET 382.

In the example of switchable tuning element 316 shown in FIG. 3, a switching FET 322 constitutes switch 321. Auxiliary FET 320 is connected in series with switching FET 322 by connecting the source of switching FET 322 to the drain of auxiliary FET 320.

Switchable tuning element 316 is additionally composed of optional switch control device 342. Switch control device 342 has an input connected to receive a tuning control signal 324 and has outputs equal in number to the number of series circuits 340 in switched tuning element 316. Each output is connected to the gate of switching FET 322 of a different one of series circuits 340 and supplies a tuning control signal element 344 to that gate. In each series circuit 340, switching FET 322 operates in response to respective tuning control signal element 344 to connect auxiliary FET 320 in parallel with main FET 302 and change the effective channel dimension of composite FET 382. The effective channel dimension is at least one of effective channel width and effective length.

Switch control device 342 may be omitted or may be located outside transconductor 300. In these cases, tuning control signal elements 344 are supplied to the gates of switching FETs 322 from outside transconductor 300.

Composite FET 384 is composed of a main FET 304 and a switchable tuning element 318 connected in parallel. Switchable tuning element 318 is composed of series circuits 350. Each series circuit 350 is composed of an auxiliary FET 330 and a switch 331 connected in series. Series circuits 350 are connected in parallel between the source and the drain of main FET 304 and the gates of auxiliary FETs 330 are connected to the gate of main FET 304. The nodes where switchable tuning element 318 connects to the drain, gate and source of main FET 304 constitute the drain, gate and source, respectively, of composite FET 384.

In the example of switchable tuning element 318 shown in FIG. 3, a switching FET 332 constitutes switch 331. Auxiliary FET 330 is connected in series with switching FET 332 by connecting the source of switching FET 332 to the drain of auxiliary FET 330.

Switchable tuning element 318 is additionally composed of optional switch control device 352. Switch control device 352 has an input connected to receive tuning control signal 324 and has outputs equal in number to the number of series circuits 350 in switched tuning element 318. Each output is connected to the gate of the switching FET 332 of a different one of series circuits 350 and supplies a tuning control signal element 354 to that gate. In each series circuit 350, switching FET 332 operates in response to respective tuning control signal element 354 to connect auxiliary FET 330 in parallel with main FET 304 and change the effective channel dimension of composite FET 384. The effective channel dimension is at least one of effective channel width and effective length.

Switch control device 352 may be omitted or may be located outside transconductor 300. In these cases, tuning control signal elements 354 are supplied to the gates of switching FETs 332 from outside transconductor 330.

Differential input voltages Vᵢₙ₊ and Vᵢₙ₋ are received via input terminal 306 and input terminal 308, respectively. Input terminal 306 is connected to the gate of composite FET 382 and input terminal 308 is connected to the gate of composite FET 384. The drains of composite FETs 382 and 384 are connected to current sources 314 and 315, respectively. The sources of composite FETs 382 and 384 are connected to one another and to a tail current sink 319. Tunable differential transconductor produces differential output currents Iₒᵤₜ₋ and Iₒᵤₜ₊ at current output 310 and current output 312, respectively. Current output 310 is located at the node between the drain of composite FET 382 and current source 314. Current output 312 is located at the node between the drain of composite FET 384 and current source 315.

Main FETs 302, 304 can be MOSFETs or J-FETs. Auxiliary FETs 320, 330 can be MOSFETs or J-FETs.

Switches 321, 331 can be MOSFETs 322, 332 as shown, J-FETs or some other type of switching elements. Switches 321, 331 having a low ON resistance provides composite FETs 382, 384 with properties that more closely match those of an individual FET. With a low ON resistance, the voltage drops across the switches are small relative to (V_{gs}−V_{T}) of the main FETs and the auxiliary FETs. In some embodiments, switching elements used as switches 321, 331 operate in response to tuning control signal 324, as described above. In other embodiments, switching elements as simple as mechanical switches, bridgeable or fusible links, for example, are used as switches 321, 331. Such switching elements do not operate in response to a tuning control signal. Switches 321, 331 may be connected in series with the sources of auxiliary FETs 320, 330, respectively, instead of in series with the drains of these FETs as in the example shown.

MOSFETs 322, 332 used as switches 321, 331 may be n-channel MOSFETs or p-channel MOSFETs, depending on the signal levels of the tuning control signal elements 344, 354.

Tuning control signal elements 344, 354 may be generated using NMOS or PMOS FETs. Typically, a full-swing CMOS logic signal is used as the tuning control signal elements.

In the example shown in FIG. 3, both of FETs 382 and 384 are composite FETs. However, this is not critical. Only one of FETs 382 and 384 need be a composite FET: the other may be an FET similar to the main FET of the composite FET. The effective channel dimension of a single composite FET may be changed as described above to tune the output offset of transconductor 200.

Tuning control signal 324 causes switch control device 342, 352 to provide tuning control signal elements 344, 354 to selected ones of switching FETs 322, 332. Tuning control signal elements 344, 354 turn ON those of switching FETs 322, 332 to which they are provided. The effective channel width of composite FET 382 is the sum of the channel width of main FET 302 and the channel widths of those of auxiliary FETs 320 connected in parallel with main FET 302 by their respective switching FETs 322 being turned ON. Similarly, the effective channel width of composite FET 384 is the sum of the channel width of main FET 304 and the channel widths of those of auxiliary FETs 330 connected in parallel with main FET 304 by their respective switching FETs 332 being turned ON.

Tunable differential transconductor 300 operates as a balanced circuit, so tuning control signal elements 334, 354 operate to turn ON corresponding ones of switching FETs 322, 324 in switchable tuning elements 316, 318 to make the effective channel widths of composite FETs 382 and 384 substantially the same. However, different tuning control signal elements may be provided to switchable tuning elements 316, 318 additionally or alternatively to tune the transconductor offset.

In switchable tuning elements 316, 318, auxiliary FETs 320, 330 can have different combinations of channel widths and can be switched ON in various combinations to provide fine control of the effective channel widths of composite FETs 382, 384, and, hence of the transconductance of tunable differential transconductor 300. In one embodiment, in switchable tuning elements 316, 318, auxiliary FETs 320, 330 have different channel widths and only a single switching FET 322, 332 in each switchable tuning element 316, 318 is switched ON at a time.

In other embodiments, more than one of switching FETs 322, 332 in each switchable tuning elements 316, 318 is switched ON at a time. In some such embodiments, in switchable tuning elements 316, 318, auxiliary FETs 320, 330 all have the same channel widths and the effective channel width is increased by switching the switchable tuning elements on using thermometer encoded control signals. In other such embodiments, the auxiliary FETs have binary-weighted channel widths and the effective channel width is increased by switching the switchable tuning elements on using binary-coded control signals. In other such embodiments, in switchable tuning elements 316, 318, auxiliary FETs 320, 330 have different channel widths. In an example, in switchable tuning elements 316, 318, auxiliary FETs 320, 330 have channel widths that are a fraction, such as a binary fraction, of the channel widths of main FETs 302, 304. In other embodiments, auxiliary FETs 320, 330 have channel widths that are integral multiples of the channel widths of main FETs 302, 304 to provide a large transconductance tuning range. The choice of auxiliary FET channel sizing and control is similar to the choices made in switched current Digital to Analog Converter designs. See, for example, T. Miki et al, An 80-MHz 8-bit CMOS D/A Converter, SC-21 IEEE J. SOLID-STATE CIRCUITS, 983-988, (1986 December).

In many embodiments, the ratio of channel width to channel length, i.e., the effective width-to-length ratio, of composite FETs 392, 384 determines the transconductance of differential transconductor 300. The width-to-length ratio can be changed by changing the channel width, the channel length, or a combination of channel width and channel length. This is done by using auxiliary FETs 320, 330 that differ in channel width, channel length, or a combination of channel width and channel length from main FETs 302, 304, respectively.

In another embodiment, in switchable tuning elements 316, 318, the channel length L_{A} of one or more of auxiliary FETs 320, 330 is different from the channel length L_{M} of main FETs 302, 304. Channel lengths may additionally or alternatively differ among auxiliary FETs. For example, a set of four auxiliary FETs may have width to-length ratios of 4W/L, 2W/L, W/L and W/2L, where L is a channel length and W is a minimum channel width. In yet another embodiment, switchable tuning elements 316, 318 each comprise auxiliary FETs having a variety of channel widths and channel lengths to achieve a particular result.

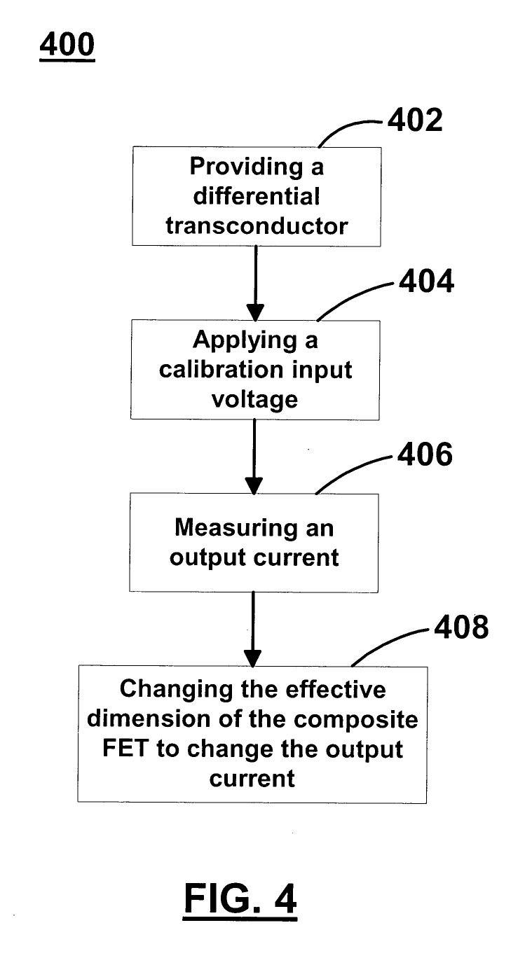

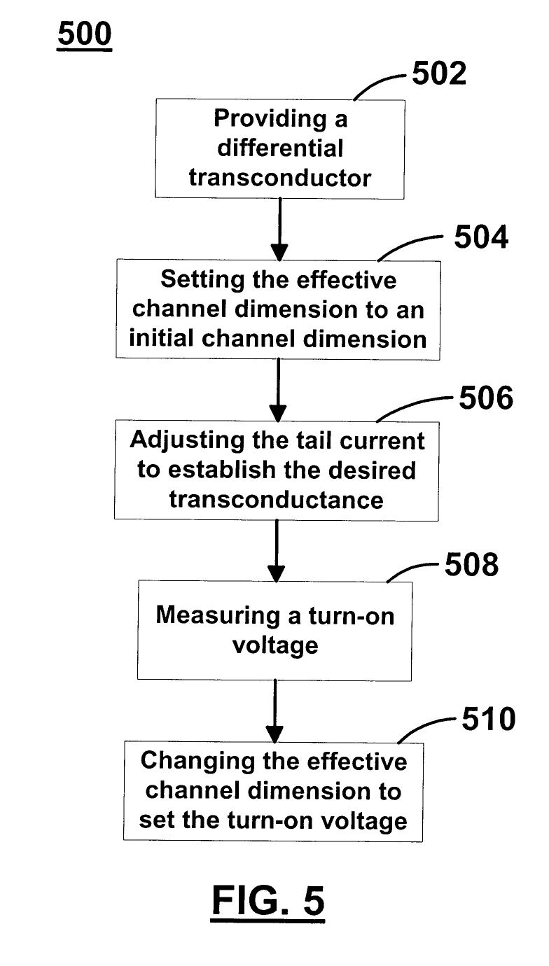

FIGS. 4 and 5 are flow charts illustrating tuning methods in accordance with the invention for tuning a tunable differential transconductor. The tunable differential transconductor in accordance with the invention provides two mechanisms for tuning transconductor performance: effective channel dimension and tail current. The tuning mechanisms can be used singly or in combination.

In a general tuning method in accordance with the invention, a differential transconductor is provided. The differential transconductor is composed of a tail current sink and a differentially-connected pair of composite FETs connected to the tail current sink. The composite FETs each have an effective channel dimension. The effective channel dimension of at least one of the composite FETs is changed to establish one or more of a desired transconductance, a desired transconductance linearity and a desired offset of the differential transconductor. The effective channel dimension is at least one of effective channel width and effective channel length.

In one embodiment, the effective channel dimension of the composite FETs is changed to establish the desired transconductance. Optionally, the tail current may additionally be adjusted to establish the desired transconductance. In this case, the range of tail current adjustment is less than that which would be required to establish the desired transconductance by tail current tuning alone. In another embodiment, the tail current is adjusted to establish a desired transconductance and the effective channel dimension is changed to establish a desired transconductance linearity in the tunable differential transconductor. Changing the effective channel dimension establishes a desired transconductance linearity by changing the value of the turn-on voltage (V_{gs}−V_{T}) for a given tail current. As noted above, increasing the turn-on voltage increases transconductance linearity.

FIG. 4 is a flow chart illustrating a first embodiment 400 of a tuning method in accordance with the invention. The tuning method can be used to tune either or both of the transconductance and transconductance linearity of a differential transconductor. Method 400 can be used to tune the transconductance of differential transconductors in which tail current tuning is ineffective, but can also be used to tune either or both of the transconductance and transconductance linearity of differential transconductors in which tail current tuning is at least partially effective. Transconductors in which tail current tuning is ineffective are those in which the FETs constituting the differentially-connected pair of FETs have a short channel length and/or a large turn-on voltage.

In method 400, in block 402, a differential transconductor including a tail current sink and a differentially-connected pair of composite FETs connected to the tail current sink is provided. The composite FETs each have an effective channel dimension.

In block 404, a calibration input voltage is applied to the differential transconductor.

In block 406, the output current of the differential transconductor is measured.

In block 408, the effective channel dimension of the composite FETs is changed to set the measured output current to a value corresponding to the product of the desired transconductance and the calibration voltage.

Since adjusting the tail current will effect some change in the transconductance of even those transconductors in which tail current tuning is regarded as being ineffective, the tail current can be adjusted in addition to changing the effective channel dimension to establish the desired transconductance. Adjusting the tail current in addition to changing the effective channel dimension is especially useful to obtain a precisely-defined transconductance when relatively few auxiliary FETs are provided, such as in the embodiment shown in FIG. 2. Replica biasing, which automatically adjusts the tail current using a replica of the differential transconductor, can be used. In one embodiment, the tail current is adjusted in addition to changing the effective channel dimension to establish the desired transconductance. In another embodiment, the tail current is adjusted to establish the desired transconductance and the effective channel dimension is changed to establish a desired transconductance linearity for the tunable differential transconductor.

FIG. 5 is a flow chart illustrating a second embodiment 500 of a tuning method in accordance with the invention for a tunable differential transconductor. Method 500 is also particularly advantageous for tuning one or more of the transconductance, the transconductance linearity and the offset of a transconductor in which tail current tuning is less effective than in the square law operating region. Even when tail current tuning is less effective than in the square law region, the combination of changing the effective channel dimension and adjusting the tail current can be used to set both the desired transconductance and the desired transconductance linearity for the tunable differential transconductor.

In method 500, in block 502, a differential transconductor that includes a tail current sink and a differentially-connected pair of composite FETs connected to the tail current sink is provided. The composite FETs each have an effective channel dimension, i.e., at least one of an effective channel width and an effective channel length.

In block 504, the effective channel dimension of the composite FETs is set to an initial value. In one embodiment, the initial value of the effective channel dimension is the maximum effective channel dimension. Adjusting the tail current provides the maximum range of adjustment of the transconductance with the effective channel dimension set to its maximum.

In block 506, the tail current is adjusted to provide the desired transconductance of the differential transconductor.

In one embodiment, the transconductance of the differential transconductor under test is adjusted using the replica bias method. In this, a replica tunable differential transconductor is provided. Typically, the tail current and channel widths of the replica differential transconductor are scaled relative to those of the differential transconductor under test. A differential calibration voltage is applied to the inputs of the replica differential transconductor. An adjustable bias current is applied to the current sinks of both the differential transconductor under test and the replica differential transconductor. The adjustable bias current is adjusted to set the differential output current of the replica differential transconductor to a value equal to the product of the differential calibration voltage and the desired transconductance. The adjusted value of the adjustable bias current sets the tail current of the differential transconductor under test to a value at which the differential transconductor under test has the desired transconductance. A servo loop applied to the replica differential transconductor may be used to perform the above adjustment automatically.

In block 508, a turn-on voltage (V_{gs}−V_{T}) is measured. In one embodiment, two more replicas of the composite FETs are used. Equal voltages are applied to the gates of the replica composite FETs. One replica composite FET is biased at the same bias current as the composite FETs in the transconductor under test, and the second replica composite FET is biased at a small fraction (e.g., 1/100) of the bias current of the composite FETs of the transconductor under test. At the low bias current, the turn-on voltage (V_{gs}−Vₜ) of the second replica composite FET is approximately zero according to equation 1. Consequently, the gate-to-source voltage V_{gs} of the second replica FET closely approximates the intrinsic threshold voltage (Vₜ) of the composite FETs. The gate-to-source voltage of the first replica composite FET is composed of the sum of the turn-on voltage (V_{gs}−Vₜ) and the threshold voltage (Vₜ) of the that device. Since the replica composite FETs have equal gate voltages, the difference in their source voltages provides a measure of the turn-on voltage of the composite FETs of the transconductor under test.

In block 510, the effective channel dimension of the composite FETs in the differential transconductor under test is changed to make the measured turn-on voltage (V_{gs}−V_{T}) equal to a desired turn-on voltage. The desired turn-on voltage provides a measure of the desired transconductance linearity of the differential transconductor under test. The relationship between turn-on voltage and linearity and the adjustment range of the effective channel dimension can be determined when the circuit is designed using standard circuit design methods. In an embodiment, a servo loop is used to compare the measured turn-on voltage of the replica composite FET with the desired turn-on voltage and to change the at least one effective channel dimension of the composite FETs of both the differential transconductor under test and the replica composite FETs to make the measured turn-on voltage equal to a desired turn-on voltage.

While the embodiments of the invention disclosed herein are presently considered preferred, various changes and modifications can be made without departing from the scope of the invention. The scope of the invention is indicated in the appended claims, and all changes that come within the meaning and range of equivalents are intended to be embraced therein.

1. A tunable differential transconductor, comprising:
a tail current sink; and
a differentially-connected pair of FETs connected to said tail current sink, at least one of said FETs being a composite FET comprising a main FET and a switchable tuning element connected in parallel, said switchable tuning element operable to change an effective channel dimension of said composite FET.

2. The tunable differential transconductor of claim 1, in which the effective channel dimension is at least one of an effective channel width and an effective channel length.

3. The tunable differential transconductor of claim 1, in which:
said switchable tuning element comprises an auxiliary FET and a switch connected in series between drain and source of said main FET; and
said auxiliary FET comprises a gate connected to the gate of said main FET.

4. The tunable differential transconductor of claim 3, in which said switch comprises a control input connected to receive a tuning control signal.

5. The tunable differential transconductor of claim 3, in which:
said switch comprises an FET; and
said control input comprises the gate of said FET.

6. The tunable differential transconductor of claim 1, in which said switchable tuning element comprises series circuits connected in parallel between source and drain of said main FET, each of said series circuits comprising an auxiliary FET and a switch connected in series, said auxiliary FET comprising a gate connected to the gate of said main FET.

7. The tunable differential transconductor of claim 6, in which said switch comprises a control input connected to receive a tuning control signal element.

8. The tunable differential transconductor of claim 7, additionally comprising a switched control device, said switched control device comprising:
an input connected to receive said control signal; and
outputs connected to deliver said tuning control signal elements to said control inputs of said switches of said series circuits.

9. The tunable differential transconductor of claim 7, in which:
said switch comprises an FET; and
said control input comprises the gate of said FET.

10. The tunable differential transconductor of claim 6, in which said series circuit comprise said auxiliary FETs of different channel dimensions.

11. The tunable differential transconductor of claim 10, in which said auxiliary FETs have channel widths equal to the channel width of said main FET divided by different integers.

12. The tunable differential transconductor of claim 10, in which said auxiliary FETs have channel widths equal to multiples of the channel width of said main FET.

13. The tunable differential transconductor of claim 1, in which both of said FETs are composite FETs each comprising a switchable tuning element connected in parallel with a respective main FET.

14. A method for tuning a differential transconductor, the method comprising:
providing said differential transconductor comprising a tail current sink and a differentially-connected pair of composite FETs connected to said tail current sink, said composite FET each having an effective channel dimension; and
changing said effective channel dimension of at least one of said composite FET to establish at least one of (a) a desired transconductance, (b) a desired transconductance linearity, and (c) a desired offset of said differential transconductor.

15. The method of claim 14, in which said effective channel dimension comprises at least one of effective channel width and effective channel length.

16. The method of claim 14, in which said changing establishes said desired transconductance, and comprises:
applying a calibration input voltage to said differential transconductor;
measuring an output current of said differential transconductor; and
changing said effective channel dimension of said composite FET to change said output current to a value corresponding to the product of said desired transconductance and said calibration input voltage.

17. The method of claim 16, additionally comprising adjusting said tail current to tune said desired transconductance.

18. The method of claim 14, additionally comprising adjusting said tail current to tune said desired transconductance.

19. The method of claim 14, in which:
said method additionally comprises:
setting said effective channel dimension to an initial channel dimension, and
adjusting said tail current to establish said desired transconductance; and
said changing comprises:
measuring a turn-on voltage of said composite FET, and
changing said effective channel dimension to set said turn-on voltage equal to a desired turn-on voltage commensurate with said desired transconductance linearity.

20. The method of claim 19, in which said initial channel dimension is a maximum effective channel dimension.

21. The method of claim 19, in which said adjusting comprises using a replica bias method.

22. The method of claim 19, in which said adjusting comprises:
applying a calibration input voltage to said differential transconductor;
measuring an output current of said differential transconductor; and
adjusting said tail current to change said output current to a value corresponding to the product of said desired transconductance and said calibration input voltage

23. The method of claim 22, in which said adjusting comprises using a replica bias method.

24. The method of claim 19, in which at least one of said setting, said adjusting, said measuring and said changing is performed on a replica of said differential transconductor.
